(19) United States
(12) Patent Application Publication
(10) Pub. No.: US 2025/0164660 A1
(43) Pub. Date: May 22, 2025

(54) DYNAMIC PRE-BALANCING IN A METAL DETECTOR

(71) Applicant: Carnes Company, Inc., Pewaukee, WI (US)

(72) Inventor: Joseph S. Simon, Jackson, WI (US)

(21) Appl. No.: 18/517,247

(22) Filed: Nov. 22, 2023

(51) Int. Cl. G01V 3/10; H01F 38/14

(52) U.S. Cl. CPC G01V 3/105; H01F 38/14

(57) ABSTRACT

Examples provide a metal detector including an array of capacitor banks and at least one resistor selectively connectable to one of a first receiver coil and a second receiver coil. The array has a plurality of capacitor bank configurations each associated with a respective capacitance value. The at least one resistor has a plurality of resistor configurations each associated with a respective resistance value. An electronic processor is configured to dynamically pre-balance the metal detector by selecting a capacitor bank configuration to assign to the first receiver coil or the second receiver coil, assigning the selected capacitor bank configuration to the first receiver coil or the second receiver coil, selecting a resistor configuration to assign to the first receiver coil or the second receiver coil, and assigning the selected resistor configuration to the first receiver coil or the second receiver coil.

### BACKGROUND

This application generally relates to balancing circuits for metal detectors.

### SUMMARY

Balancing circuits for metal detectors often use a highly precise set of components and programming that maintains a balance in the metal detector by adjusting a resistance and/or a capacitance that is applied to coils of the metal detector. These balancing circuits have a limit on how much resistance and/or capacitance can be shifted, or “focused,” in order to identify and maintain balancing precision. Therefore, metal detectors also undergo a pre-balance, or “macro balance” procedure to bring the system into focus well enough to allow a precision balancing circuit to fine tune the balance configuration. Conventional pre-balance procedures are performed by a technician at initial setup of the metal detector, and include attaching a physical pre-balance sub-board to a main circuit board of the metal detector. The technician then solders large static capacitors and/or resistors onto the sub-board in a combination that successfully pre-balances or pre-focuses the system into a “ballpark” range.

After installation of the sub-board, the pre-balance on the metal detector cannot be changed without replacing the sub-board. However, changes to the metal detector (e.g., changes caused by use over time, damage to the metal detector, etc.), changes in the environment surrounding the metal detector (e.g., temperature, humidity, etc.), and/or changes in the end application of the metal detector may sufficiently defocus the metal detector such that the precision-balance circuit is no longer within the macro-balance range required to precision balance the metal detector. When such changes occur, a technician must add or subtract resistors and/or capacitors to the sub-board and perform the macro-balance procedure again.

Thus, there is a need for a dynamic pre-balancing solution that does not require physical replacement of the pre-balance components of the metal detector.

In some aspects, the techniques described herein relate to a metal detector including: a set of coils including a first receiver coil, a second receiver coil, and a transmitter coil; an array of capacitor banks selectively connectable to one of the first receiver coil, the second receiver coil, or neither receiver coil, the array having a plurality of capacitor bank configurations, each capacitor bank configuration associated with a respective capacitance value; at least one resistor selectively connectable to one of the first receiver coil, the second receiver coil, or neither receiver coil, the at least one resistor having a plurality of resistor configurations, each resistor configuration associated with a respective resistance value; and an electronic processor configured to dynamically pre-balance the set of coils by: selecting a capacitor bank configuration to assign to one of the first receiver coil, the second receiver coil, or neither receiver coil, assigning the selected capacitor bank configuration to one of the first receiver coil, the second receiver coil, or neither receiver coil, selecting a resistor configuration to assign to one of the first receiver coil, the second receiver coil, or neither receiver coil, and assigning the selected resistor configuration to one of the first receiver coil, the second receiver coil, or neither receiver coil.

In some aspects, the techniques described herein relate to a method for dynamically pre-balancing a metal detector, the method including: selecting one of a plurality of capacitor bank configurations defined by an array of capacitor banks to assign to one of a first receiver coil, a second receiver coil, or neither receiver coil, wherein each capacitor bank configuration is associated with a respective capacitance value; assigning the selected one of the plurality of capacitor bank configurations to one of the first receiver coil, the second receiver coil, or neither receiver coil; selecting one of a plurality of resistor configurations defined by at least one resistor to assign to one of the first receiver coil, the second receiver coil, or neither receiver coil, wherein each resistor configuration associated with a respective resistance value; and assigning the selected resistor configuration to one of the first receiver coil, the second receiver coil, or neither receiver coil.

In some aspects, the techniques described herein relate to a balancing circuit for a metal detector, the balancing circuit including: an array of capacitor banks selectively connectable to one of a first receiver coil, a second receiver coil, or neither receiver coil, the array having a plurality of capacitor bank configurations, each capacitor bank configuration associated with a respective capacitance value; at least one resistor selectively connectable to one of the first receiver coil, the second receiver coil, or neither receiver coil, the at least one resistor having a plurality of resistor configurations, each resistor configuration associated with a respective resistance value; and an electronic processor configured to dynamically pre-balance the metal detector by: selecting a capacitor bank configuration to assign to one of the first receiver coil, the second receiver coil, or neither receiver coil, assigning the selected capacitor bank configuration to one of the first receiver coil, the second receiver coil, or neither receiver coil, selecting a resistor configuration to assign to one of the first receiver coil, the second receiver coil, or neither receiver coil, and assigning the selected resistor configuration to one of the first receiver coil, the second receiver coil, or neither receiver coil.

Other aspects of the invention will become apparent by consideration of the detailed description and accompanying drawings.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments, examples, aspects, and features of concepts that include the claimed subject matter and explain various principles and advantages of those embodiments, examples, aspects, and features.

FIG. 1 illustrates a perspective view of a metal detector, according to some examples.

FIG. 2 illustrates a block diagram of a metal detector, according to some examples.

FIG. 3 illustrates a block diagram of a pre-balance circuit in a metal detector, according to some examples.

FIG. 4 schematically illustrates a pre-balance circuit in a metal detector, according to some examples.

FIG. 5 illustrates a method for balancing a metal detector, according to some examples.

FIG. 6 illustrates a method for pre-balancing a metal detector, according to some examples.

FIG. 7 illustrates a method for phase pre-balancing a metal detector, according to some examples.

FIG. 8 illustrates a method for amplitude pre-balancing a metal detector, according to some examples.

FIG. 9A illustrates a method for selecting a capacitor configuration for phase pre-balancing a metal detector, according to some examples.

FIG. 9B illustrates a continuation of a method for selecting a capacitor configuration for phase pre-balancing a metal detector, according to some examples.

FIG. 10 illustrates a method for assigning a capacitor configuration to a metal detector receiver coil, according to some examples.

FIG. 11A illustrates a method for selecting a resistor configuration for amplitude pre-balancing a metal detector, according to some examples.

FIG. 11B illustrates a continuation of a method for selecting a capacitor configuration for amplitude pre-balancing a metal detector, according to some examples.

FIG. 12 illustrates a method for assigning a resistor configuration to a metal detector receiver coil, according to some examples.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of examples, aspects, and features illustrated.

In some instances, the apparatus and method components have been represented where appropriate by conventional symbols in the drawings, showing only those specific details that are pertinent to understanding the of various embodiments, examples, aspects, and features so as not to obscure the disclosure with details that will be readily apparent to those of ordinary skill in the art having the benefit of the description herein.

### DETAILED DESCRIPTION

Before any examples are explained in detail, it is to be understood that the examples presented herein are not limited in their application to the details of construction and the arrangement of components set forth in the following description or illustrated in the following drawings. The examples are capable of other embodiments and of being practiced or of being carried out in various ways. For ease of description, the example systems presented herein may be illustrated with a single exemplar of each of its component parts. Some examples may not describe or illustrate all components of the systems. Other example embodiments may include more or fewer of each of the illustrated components, may combine some components, or may include additional or alternative components.

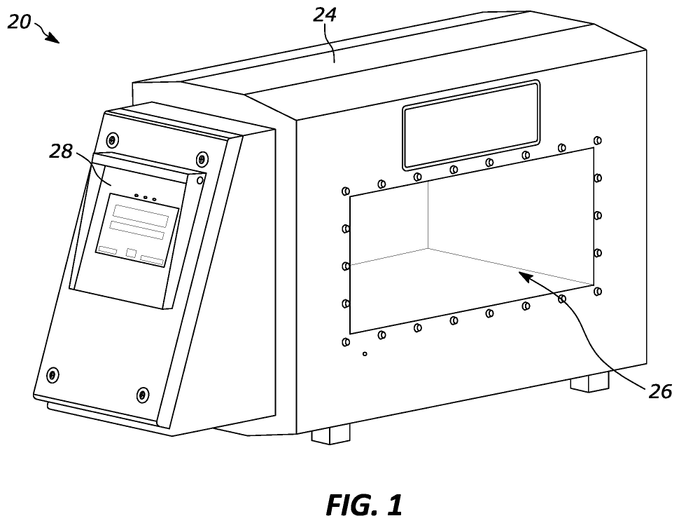

FIG. 1 illustrates an example metal detector 20, according to some aspects. The metal detector 20 may be a commercial metal detector 20 used in food processing, mining, recycling, wood processing, or the like. However, in some instances, the metal detector 20 is a recreational metal detector 20. The metal detector 20 includes a housing 24 defining a passageway 26 for receiving an object to be scanned. The metal detector 20 also includes a user interface 28 for providing user control of the metal detector 20. The user interface 28 may include a display for providing a user with information relating to the status of the metal detector 20 and/or information relating to an object scanned by the metal detector 20.

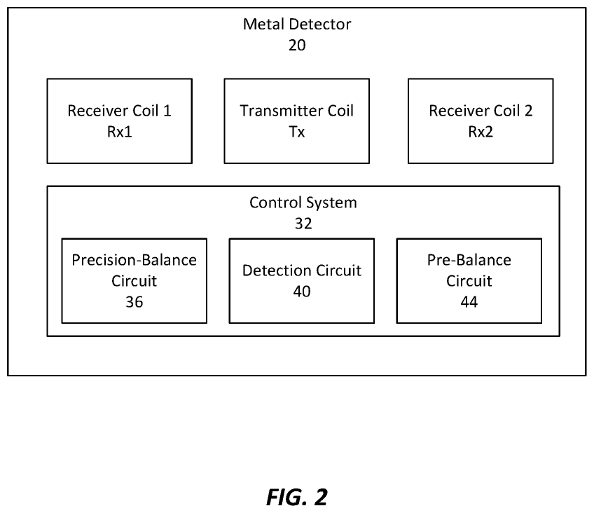

FIG. 2 illustrates a block diagram of the metal detector 20, according to some aspects. The metal detector 20 includes a first receiver coil Rx1, a second receiver coil Rx2, and a transmitter coil Tx, each surrounding the passageway 26 illustrated in FIG. 1. The first receiver coil Rx1 and the second receiver coil Rx2 are positioned on opposite sides of the transmitter coil Tx and substantially equidistant from the transmitter coil Tx.

The metal detector 20 also includes a control system 32 having a precision-balance circuit 36 for precision balancing the metal detector 20 and a detection circuit 40 for detecting metal contained in objects passing through the passageway 26 of the metal detector 20.

During operation of the metal detector 20, the control system 32 (e.g., using the detection circuit 40) supplies an oscillatory signal to the transmitter coil Tx. The transmitter coil Tx transmits a signal based on the received oscillatory signal, and the first receiver coil Rx1 and the second receiver coil Rx2 receive the transmitted signal, for example, by means of inductive coupling with the transmitter coil Tx. Based on the signal received from the transmitter coil Tx, the first receiver coil Rx1 and the second receiver coil Rx2 each generate a respective receiver output signal.

The detection circuit 40 compares the respective receiver output signals and determines a difference between the signals. When there is no material in the passageway 26 and the metal detector 20 is precisely balanced, the signals received by the respective receiver coils Rx1 and Rx2 are substantially equal to one another, and the signals output by the respective receiver coils Rx1 and Rx2 are substantially equal to one another. For example, each receiver output signal includes an amplitude component and a phase component. When the metal detector 20 is balanced and no material is in the passageway 26, the amplitude component of the signal output by the first receiver coil Rx1 is substantially equal to the amplitude component of the signal output by the second receiver coil Rx2. Similarly, when the metal detector 20 is balanced and no material is in the passageway 26, the phase component of the signal output by the first receiver coil Rx1 is substantially equal to the phase component of the signal output by the second receiver coil Rx2. In such instances, the detection circuit 40 may output a result signal indicating that the difference between the respective receiver output signals is zero. The result signal may be referred to herein as a balance voltage or balance voltage signal.

When an object enters the passageway 26, the signals received by, and therefore output by, the first receiver coil Rx1 and the second receiver coil Rx2 differ. For example, either one or both of the amplitude and the phase angle of the respectively output signals may differ from one another. In such instances, the balance voltage output by the detection circuit 40 as a result of a comparison of the respective receiver output signals is non-zero. When the object passing through the passageway 26 contains metal, the metal emits a signal equal in frequency to that of the transmitter. This emitted signal is first received by the coil nearer to the metal, thus causing a previously balanced output to become imbalanced. Therefore, a receiver coil nearer the metal receives a greater signal than a receiver coil that is farther away from the metal. Accordingly, the output signals of the first receiver coil Rx1 and the second receiver coil Rx2 differ from one another more than in instances where the object does not contain metal, and this larger difference is reflected by the balance voltage signal output by the detection circuit 40.

As described above, when the metal detector 20 is balanced and no material is in the passageway 26, the respective receiver output signals are substantially equal to one another, and the balance voltage signal is zero. However, environmental changes to the metal detector 20 and/or damage sustained to the metal detector 20 may shift the balance of the metal detector 20, and cause the first receiver coil Rx1 and the second receiver coil Rx2 to output differing signals even when no material is in the passageway 26. The precision balancing circuit 36 may be used to resolve minor variations in the respective receiver output signals by adjusting a resistance and/or a capacitance associated with a respective receiver coil. However, in some instances, the difference between the respective receiver output signals varies beyond what the precision balancing circuit 36 is able to mitigate. For example, in some instances, a precision balance circuit is limited to a range of approximately 24 Volts peak-to-peak (“Vp-p”) for a first stage of amplification and 24 Vp-p for a last stage of amplification. Rather than requiring a technician to manually macro-balance the metal detector 20 by replacing resistive and capacitive components on a pre-balance sub-board so that the precision balance circuit 36 is in range to operate, the metal detector 20 described herein further includes a dynamic pre-balance circuit 44 in the control system 32.

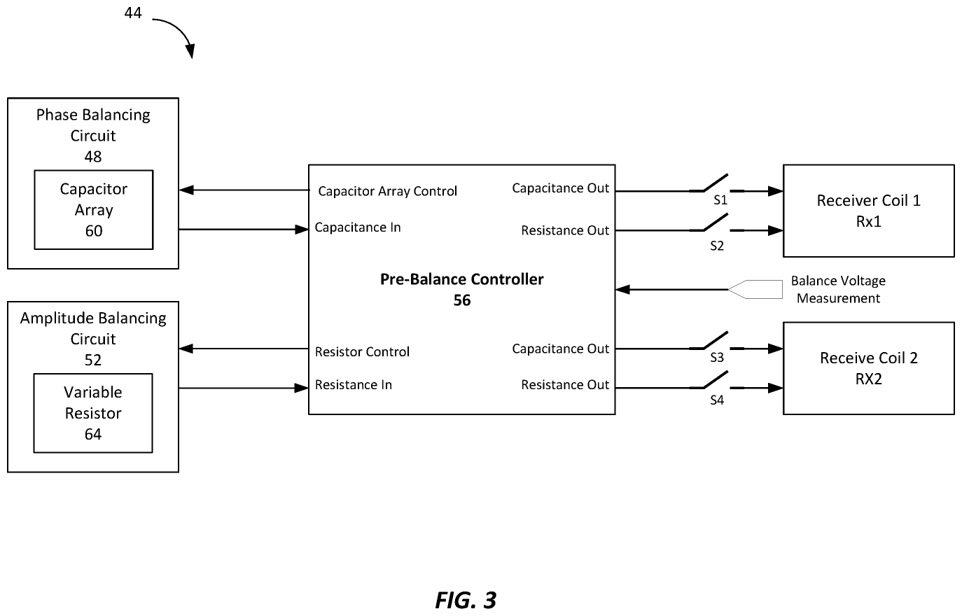

FIG. 3 illustrates a block diagram of the pre-balance circuit 44, according to some examples. The pre-balance circuit 44 includes a phase balancing circuit 48, an amplitude balancing circuit 52, and a pre-balance controller 56 electrically connected to the phase balancing circuit 48 and the amplitude balancing circuit 52. The pre-balance controller receives a capacitance value output from a capacitor array 60 included in the phase balancing circuit 48, and receives a resistance value output from at least one resistor 64 included in the amplitude balancing circuit 52.

The pre-balance controller 56 is configured to balance the phase of the receiver coils by selectively providing capacitance output from the phase balancing circuit 48 to one of the first receiver coil Rx1, the second receiver Rx2, or neither receiver coil by opening or closing switches S1 and S3. For ease of explanation, the pre-balance controller is illustrated and described herein as a single controller. However, the pre-balance controller may be implemented using more than one controller. For example, the pre-balance controller 56 may be implemented in a distributed manner in the metal detector 20. Additionally, while illustrated in FIG. 3 as two switches respectively connectable to the first receiver coil Rx1 and the second receiver coil Rx2, the switches S1 and S3 may alternatively be implemented as single switch connectable to the first receiver coil Rx1, the second receiver coil Rx2, or neither receiver coil. Other switching configurations are contemplated as well.

The capacitor array 60 is an array of selectively connectable capacitor banks, with each bank associated with a predetermined capacitance value. The capacitor array 60 defines a plurality of capacitor bank configurations. In some instances, the capacitor array 60 may be an 8 bit array of capacitor banks having 256 capacitor bank configurations. For example, the capacitor array 60 may include 8 capacitor banks respectively having a capacitance of 100 picofarads (“pf”), 200 pf, 400 pf, 800 pf, 1.6 nanofarads (“nf”), 3.2 nf, 6.4 nf, and 12.8 nf. The capacitance value output by the capacitor array 60 may therefore range from 0 pf to 25.5 nf with a resolution of 100 pf. However, the values associated with each capacitor bank and the number of capacitor banks included in the capacitor array 60 are not limited to those described herein, and other array sizes and capacitance values are contemplated. For example, in some instances, the capacitor array 60 is a 12 bit array having 4096 capacitor bank configurations, each configuration associated with a different capacitance value.

The pre-balance controller 56 controls the capacitor bank configuration of the capacitor array 60 by outputting a control signal to control a switching configuration of the capacitor array 60 in order to select one of the plurality of capacitor bank configurations to assign to a receiver coil Rx1 or Rx2.

The pre-balance controller 56 is configured to balance the amplitude of the receiver coils by selectively providing resistance output from the amplitude balancing circuit 52 to one of the first receiver coil Rx1, the second receiver Rx2, or neither receiver coil by opening or closing switches S2 and S4. While illustrated in FIG. 3 as two switches respectively connectable to the first receiver coil Rx1 and the second receiver coil Rx2, the switches S2 and S4 may alternatively be implemented as single switch connectable to the first receiver coil Rx1, the second receiver coil Rx2, or neither receiver coil. Other switching configurations are contemplated as well.

The at least one resistor 64 defines a plurality of resistor configurations each associated with a respective resistance value (expressed in Ohms (Ω)). For example, the at least one resistor 64 may include 256 resistor configurations ranging from 0Ω to 50Ω with a resolution of approximately 196 2. In some instances, the at least one resistor 64 is a plurality of resistors 64 having the same or difference resistances and selectively connectable to one another. However, in some instances, the at least one resistor 64 is a single variable resistor 64 (e.g., a potentiometer). For example, the at least one resistor 64 may be a 0-50 kΩ digital potentiometer. The at least one resistor 64 may be referred to herein as variable resistor 64. The pre-balance controller 56 controls the resistor configuration of the variable resistor 64 by outputting a control signal to the amplitude balancing circuit 52 for adjusting resistance generated by the variable resistor 64 and assigned to a receiver coil Rx1 or Rx2.

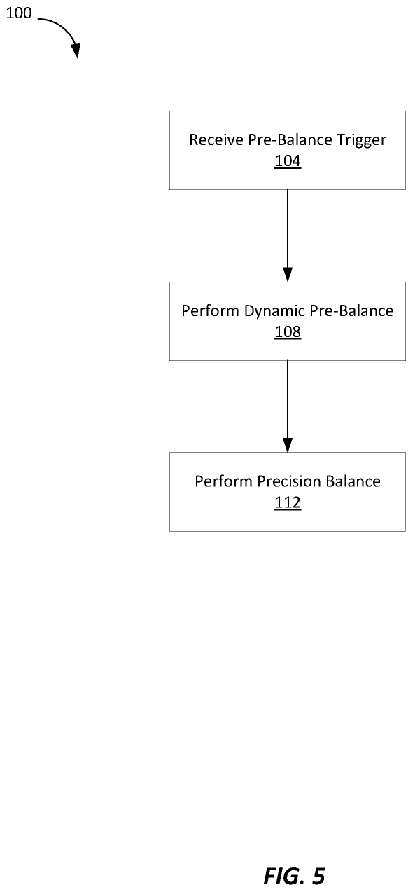

The pre-balance controller 56 controls the phase balancing circuit 48, the amplitude balancing circuit 52, and the switches S1-S4 based on a balance voltage signal received from, for example, the detection circuit 40. Methods for controlling the phase balancing circuit 48, the amplitude balancing circuit 52, and the switches S1-S4 will be described in greater detail below with respect to FIGS. 5-12.

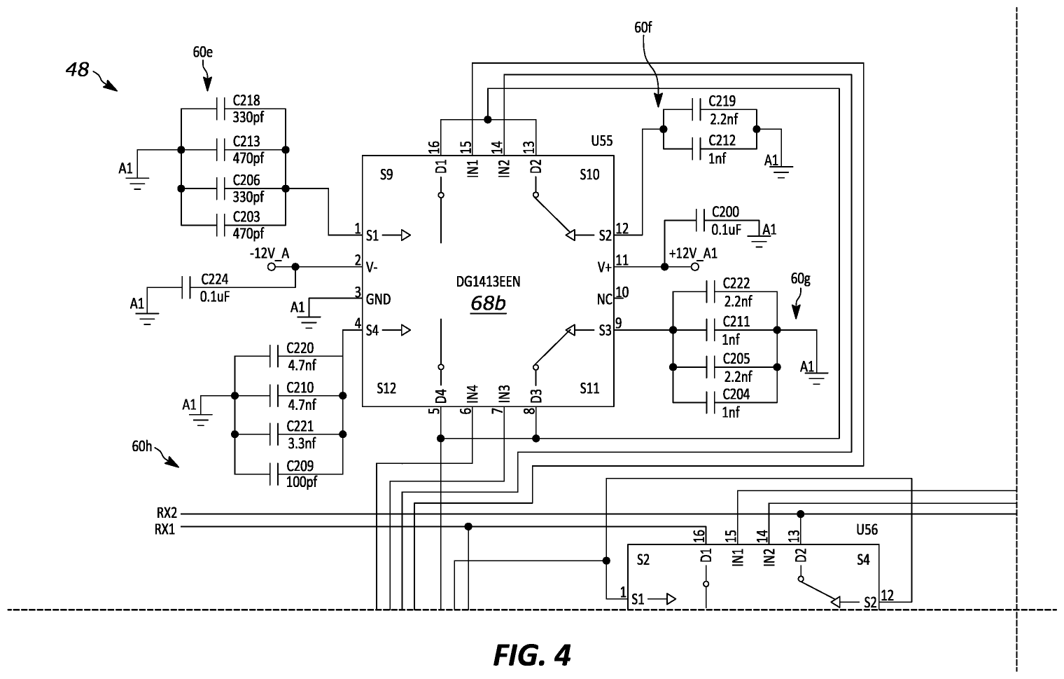

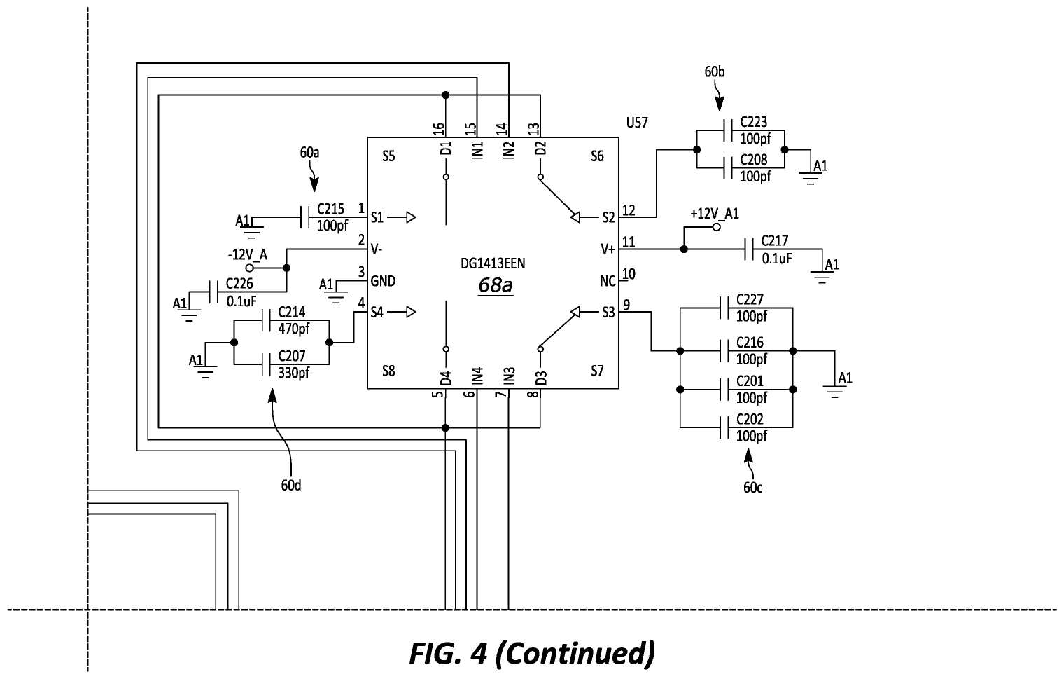

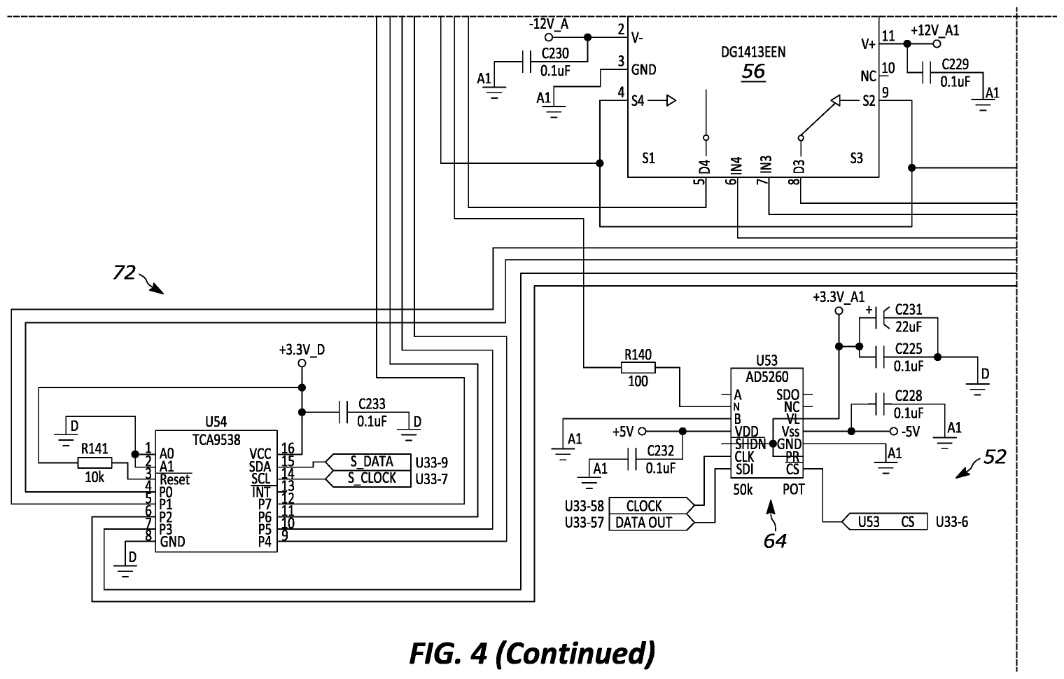

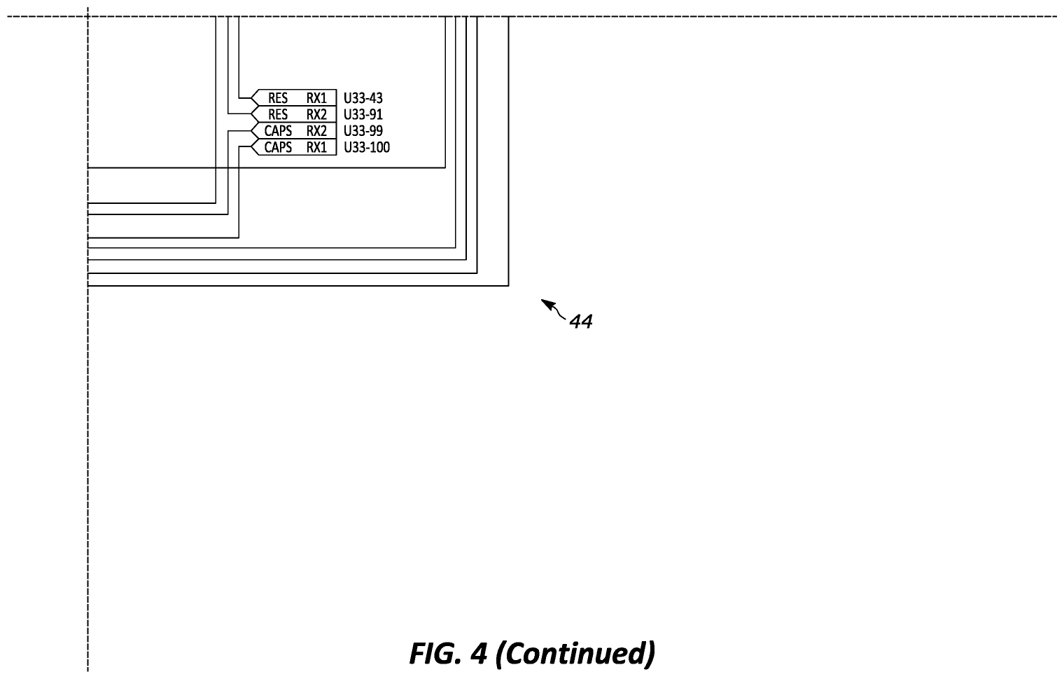

FIG. 4 schematically illustrates the pre-balance circuit 44, according to some examples. In the example illustrated in FIG. 4, the phase balancing circuit 48 includes two phase balancing controllers 68a and 68b each including a plurality of switches for electrically connecting respective capacitor banks included in the capacitor array 60. A first phase controller 68a includes four switches S5-S8 for respectively connecting capacitor banks 60a to 60d, which are respectively associated with capacitance values of 100 pf, 200 pf, 400 pf, and 800 pf. A second phase controller 68b includes four switches S9-S12 for respectively connecting capacitor banks 60e to 60h, which are respectively associated with capacitance values of 1.6 nf, 3.2 nf, 6.4 nf, and 12.8 nf. In some instances, each of the switches S5-S12 may be driven via an input/output (“I/O”) expander 72.

While FIG. 4 is illustrated as having two phase controllers 68a and 68b each connectable to four capacitor banks, it should be understood that, in some instances, the pre-balance circuit 44 includes only one phase controller that is connectable to less than four capacitor banks or more than four capacitor banks (e.g., 8 capacitor banks, 12 capacitor banks, etc.). Additionally, in some instances, the pre-balance circuit 44 does not include the I/O expander 72.

The phase controllers 68a and 68b selected capacitance values to the pre-balance controller 56, which in turn selectively assigns the capacitance to the first receiver coil Rx1 or the second receiver coil Rx2 by controlling switches S1 and S3. Similarly, the variable resistor 64, shown in FIG. 4 a 0−+k Ω model AD5262 manufactured by Analog Devices, outputs a resistance value to the pre-balance controller 56, which in turn selectively assigns the resistance to the first receiver Rx1 or the second receiver Rx2 by controlling switches S2 and S4.

Referring now to FIG. 5, an example method 100 for balancing a metal detector (e.g., the metal detector 20) is illustrated. The method includes receiving, for example, with the pre-balance circuit 44, a pre-balance trigger that causes the pre-balance circuit 44 to initiate a pre-balancing, or macro-balancing, procedure (at block 104). In some instances, the pre-balance trigger is a power on signal generated in response to power being supplied to the metal detector 20. For example, the method 100 may be performed each time that the metal detector 20 starts up. In some instances, the pre-balance trigger is generated in response to the balance voltage output by the detection circuit 40, and indicating a difference between output signals of the receiver coils Rx1 and Rx2, exceeds a threshold balance voltage. In some instances, the pre-balance trigger is generated in response to user input received via the user interface 28.

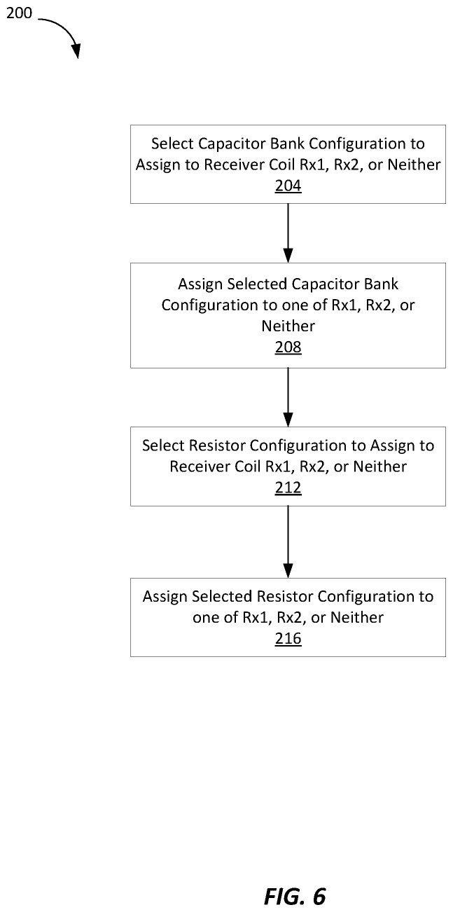

In response to receiving the pre-balance trigger, the pre-balance circuit 44 automatically performs a dynamic pre-balance of the metal detector 20 (at block 108). For example, FIG. 6 illustrates an example method 200 for performing dynamic pre-balance of the metal detector 20. The method 200 includes selecting, with the pre-balance controller 56, a capacitor bank configuration of the capacitor array 60 to assign to one of the first receiver coil Rx1, the second receiver coil Rx2, or neither receiver coil (at block 204), and assigning the selected capacitor bank configuration to one of the first receiver coil Rx1, the second receiver coil Rx2, or neither receiver coil (at block 208). The method 200 also includes selecting, with the pre-balance controller 56, a resistor configuration of the variable resistor 64 to assign to one of the first receiver coil Rx1, the second receiver coil Rx2, or neither receiver coil (at block 212), and assigning the selected resistor configuration to one of the first receiver coil Rx1, the second receiver coil Rx2, or neither receiver coil (at block 216).

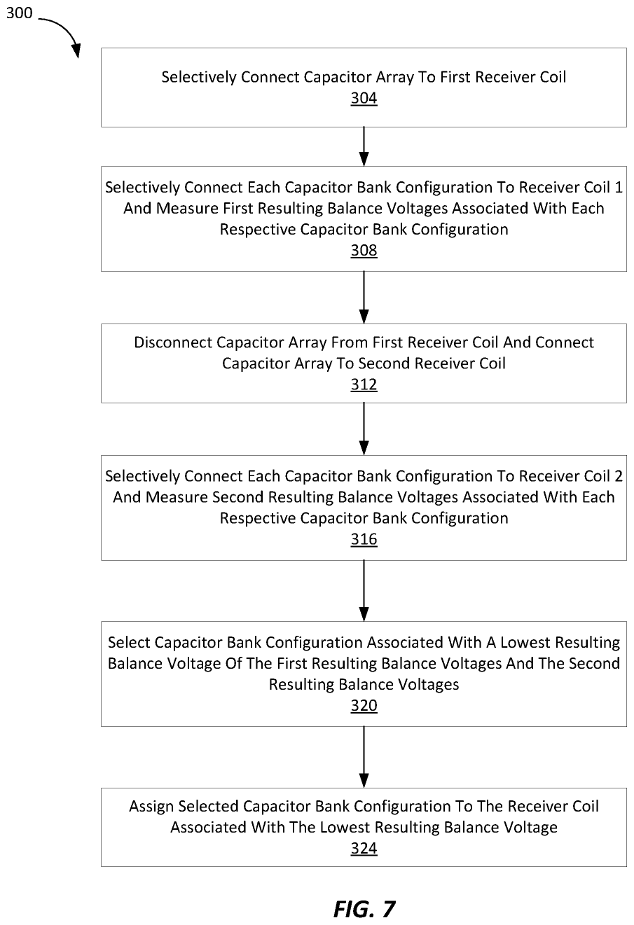

FIG. 7 illustrates an example method 300 for selecting and assigning a capacitor bank configuration of the capacitor array 60 to one of the first receiver coil Rx1, the second receiver coil Rx2, or neither receiver coil (at blocks 204 and 208 of the method 200). The method 300 includes selectively connecting the capacitor array 60 to the first receiver coil Rx1 (e.g., by opening the switch S3 and closing the switch S1) (at block 304). The pre-balance controller 56 selectively connects (e.g., by outputting a control signal to the phase balancing circuit 52) each capacitor bank configuration of the plurality of capacitor bank configurations defined by the capacitor array 60 to the first receiver coil Rx1, and measures first resulting balance voltages associated with each respective capacitor bank configuration when the respective capacitor bank configuration is connected to the first receiver coil Rx1 (at block 308).

The pre-balance controller 56 disconnects the capacitor array 60 from the first receiver coil Rx1 and connects the capacitor array 60 to the second receiver coil Rx2 (e.g., by opening the switch S1 and closing the switch S3) (at block 312). The pre-balance controller 56 selectively connects (e.g., by outputting a control signal to the phase balancing circuit 52) each capacitor bank configuration of the plurality of capacitor bank configurations defined by the capacitor array 60 to the second receiver coil Rx2, and measures second resulting balance voltages associated with each respective capacitor bank configuration when the respective capacitor bank configuration is connected to the second receiver coil Rx2 (at block 316).

After measuring the first resulting balance voltages (at block 308) and the second resulting balance voltages (at block 316) associated with each of the plurality of capacitor bank configurations, the pre-balance controller 56 selects a capacitor bank configuration associated with a lowest resulting balance voltage of the first resulting balance voltages and the second resulting balance voltages (at block 320). For example, the pre-balance controller 56 selects one resulting balance voltage that is associated with a particular capacitor bank configuration that, when the particular capacitor bank configuration is connected to a particular receiver coil (e.g., either the first receiver coil Rx1 or the second receiver coil Rx2), results in a lowest balance voltage of the metal detector 20. The pre-balance controller 56 assigns the selected capacitor bank configuration to the particular receiver coil that is associated with the lowest resulting balance voltage (at block 324).

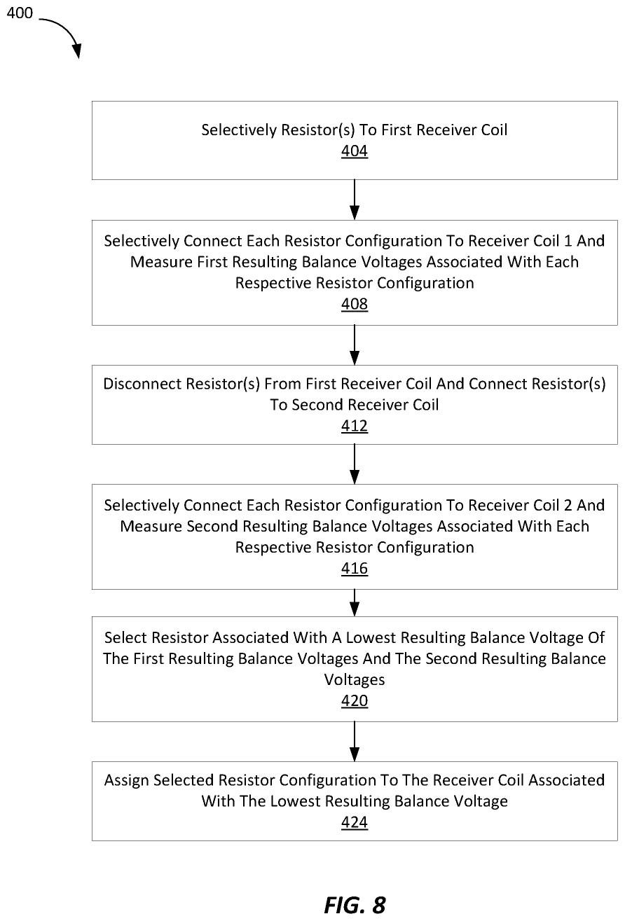

FIG. 8 illustrates an example method 400 for selecting and assigning a resistor configuration to one of the first receiver coil Rx1, the second receiver coil Rx2, or neither receiver coil (at blocks 212 and 216 of the method 200). The method 400 includes selectively connecting the variable resistor 64 to the first receiver coil Rx1 (e.g., by opening the switch S4 and closing the switch S2) (at block 404). The pre-balance controller 56 selectively connects (e.g., by outputting a control signal to the amplitude balancing circuit 52) each resistor configuration of the plurality of resistor configurations of the variable resistor 64 to the first receiver coil Rx1, and measures first resulting balance voltages associated with each respective resistor configuration when the respective resistor configuration is connected to the first receiver coil Rx1 (at block 408).

The pre-balance controller 56 disconnects the variable resistor 64 from the first receiver coil Rx1 and connects the variable resistor 64 to the second receiver coil Rx2 (e.g., by opening the switch S2 and closing the switch S4) (at block 412). The pre-balance controller 56 selectively connects (e.g., by outputting a control signal to the amplitude balancing circuit 52) each resistor configuration of the plurality of resistor configurations to the second receiver coil Rx2, and measures second resulting balance voltages associated with each respective resistor configuration when the respective resistor configuration is connected to the second receiver coil Rx2 (at block 416).

After measuring the first resulting balance voltages (at block 408) and the second resulting balance voltages (at block 416) associated with each of the plurality of resistor configurations, the pre-balance controller 56 selects a resistor configuration associated with a lowest resulting balance voltage of the first resulting balance voltages and the second resulting balance voltages (at block 420). For example, the pre-balance controller 56 selects one resulting balance voltage that is associated with a particular resistor configuration that, when the particular resistor configuration is connected to a particular receiver coil (e.g., either the first receiver coil Rx1 or the second receiver coil Rx2), results in a lowest balance voltage of the metal detector 20. The pre-balance controller 56 assigns the selected resistor configuration to the particular receiver coil that is associated with the lowest resulting balance voltage (at block 424).

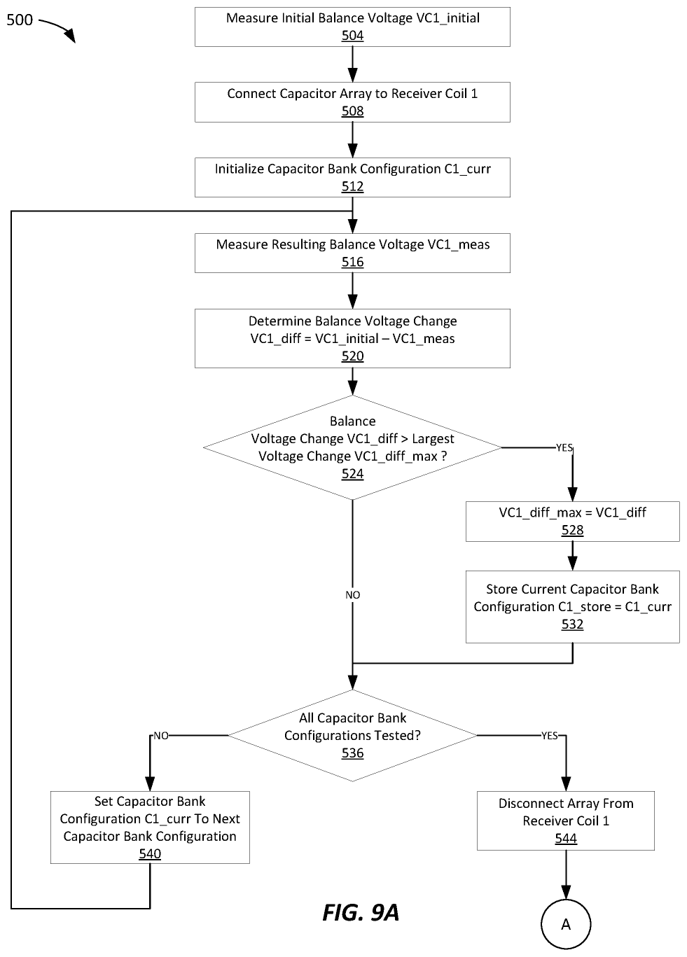

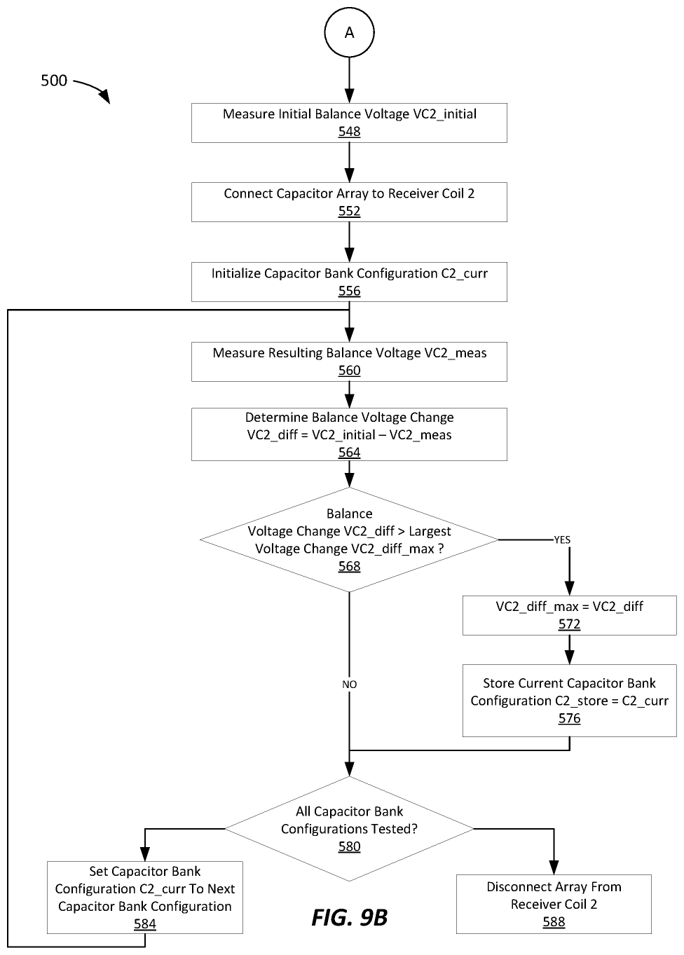

FIGS. 9A and 9B illustrate an example method 500 for selecting a capacitor bank configuration of the capacitor array 60 to assign to one of the first receiver coil Rx1, the second receiver coil Rx2, or neither receiver coil (at block 204 of FIG. 6). Referring now to FIG. 9A, the method 500 includes measuring an initial balance voltage VC1_initial of the metal detector 20, for example, using the detection circuit 30 (at block 504). The initial balance voltage VC1_initial indicates a balance voltage of the metal detector 20 when no objects are present in the passageway 26 and no capacitance or resistance is applied to receiver coil Rx1 or receiver coil Rx2 (e.g., when all of switches S1-S4 are open).

The pre-balance controller 56 connects the capacitor array 60 to the first receiver coil Rx1 (e.g., by closing the switch S1) (at block 508), and initializes a capacitor bank configuration C1_curr of the capacitor array 60 (at block 512) by outputting a control signal to the phase balancing circuit 48. The pre-balance controller 56 may initialize the capacitor bank configuration C1_curr to a first capacitance value of the predetermined range of capacitance values of the capacitor array 60. For example, the initial capacitor bank configuration C1_curr may be a capacitor bank configuration associated with 0 farads, associated with a smallest capacitor bank capacitance (e.g., 100 pf), or associated with a largest capacitor bank capacitance (e.g., 12.8 nf).

When the capacitor bank configuration C1_curr is set, the pre-balance circuit 44 measures (e.g., by way of the detection circuit 40) a resulting balance voltage VC1_meas of the metal detector 20 (at block 516). The pre-balance controller determines a balance voltage change VC1_diff defined by the difference between the initial balance voltage VC1_initial and the resulting balance voltage VC1_meas (at block 520).

The pre-balance controller 56 then determines whether the balance voltage change VC1_diff is greater than a largest voltage change VC1_diff_max (e.g., a greatest decrease in balance voltage) determined during a current execution of the method 500 (at block 524). For example, at an initial iteration of block 524, the value of VC1_diff_max may be zero. When the balance voltage change VC1_diff is greater than a largest voltage change VC1_diff_max (“YES” at block 524), the pre-balance controller replaces a stored value of the largest voltage change VC1_diff_max with the value of the balance voltage change VC1_diff (at block 528). When the balance voltage change VC1_diff is greater than a largest voltage change VC1_diff_max (“YES” at block 524), the pre-balance controller also stores capacitor bank configuration C1_store with the current capacitor bank configuration C1_curr (at block 532).

When the balance voltage change VC1_diff is not greater than a largest voltage change VC1_diff_max (“NO” at block 524), the method 500 proceeds to block 536. At block 536, the pre-balance controller 56 determines whether all capacitor bank configurations defined by the capacitor array 60 have been tested with respect to the first receiver coil Rx1. When less than all the capacitor bank configurations defined by the capacitor array 60 have been tested with respect to the first receiver coil Rx1 (“NO” at block 536), the pre-balance controller 56 outputs a control signal to the phase balancing circuit 48 to set the current capacitor bank configuration C1_curr to a next capacitor bank configuration (at block 540), and repeats the steps defined by blocks 516-544 of the method 500. For example, in response to receiving the control signal (e.g., generated at block 540), the phase balancing circuit 48 controls one or more of the switches S5 -S12 to connect a next capacitor bank configuration defined by the capacitor array 60.

When all the capacitor bank configurations defined by the capacitor array 60 have been tested with respect to the first receiver coil Rx1 (“YES” at block 536), the pre-balance controller 56 disconnects the capacitor array 60 from the first receiver coil Rx1 (e.g., by opening the switch S1) (at block 544).

Referring now to FIG. 9B, illustrating a continuation of the method 500, the pre-balance controller 56 measures an initial balance voltage VC2_initial of the metal detector 20 with capacitor array 60 disconnected from both the first receiver coil Rx1 and the second receiver coil Rx2 (at block 548). However, in some instances, the pre-balance controller 56 measures the initial balance voltage only once (e.g., at block 548).

The pre-balance controller 56 connects the capacitor array 60 to the second receiver coil Rx2 (e.g., by closing the switch S3) (at block 552), and initializes a capacitor bank configuration C2_curr of the capacitor array 60 (at block 556) by outputting a control signal to the phase balancing circuit 48. The pre-balance controller 56 may initialize the capacitor bank configuration C2_curr to a first capacitance value of the predetermined range of capacitance values of the capacitor array 60. For example, the initial capacitor bank configuration C2_curr may be a capacitor bank configuration associated with 0 farads, associated with a smallest capacitor bank capacitance (e.g., 100 pf), or associated with a largest capacitor bank capacitance (e.g., 12.8 nf).

When the capacitor bank configuration C2_curr is set, the pre-balance circuit 44 measures (e.g., by way of the detection circuit 40) a resulting balance voltage VC2_meas of the metal detector 20 (at block 560). The pre-balance controller determines a balance voltage change VC2_diff defined by the difference between the initial balance voltage VC2_initial and the resulting balance voltage VC2_meas (at block 564).

The pre-balance controller 56 then determines whether the balance voltage change VC2_diff is greater than a largest voltage change VC2_diff_max (e.g., a greatest decrease in balance voltage) determined during a current execution of the method 500 (at block 568). For example, at an initial iteration of block 568, the value of VC2_diff_max may be zero. When the balance voltage change VC2_diff is greater than a largest voltage change VC2_diff_max (“YES” at block 568), the pre-balance controller replaces a stored value of the largest voltage change VC2_diff_max with the value of the balance voltage change VC 2_diff (at block 572). When the balance voltage change VC2_diff is greater than a largest voltage change VC2_diff_max (“YES” at block 568), the pre-balance controller also stores capacitor bank configuration C2_store with the current capacitor bank configuration C2_curr (at block 576).

When the balance voltage change VC2_diff is not greater than a largest voltage change VC2_diff_max (“NO” at block 568), the method 500 proceeds to block 580. At block 580, the pre-balance controller 56 determines whether all capacitor bank configurations defined by the capacitor array 60 have been tested with respect to the second receiver coil Rx2. When less than all the capacitor bank configurations defined by the capacitor array 60 have been tested with respect to the second receiver coil Rx2 (“NO” at block 580), the pre-balance controller 56 outputs a control signal to the phase balancing circuit 48 to set the current capacitor bank configuration C2_curr to a next capacitor bank configuration (at block 584), and repeats the steps defined by blocks 560-588 of the method 500. For example, in response to receiving the control signal (e.g., generated at block 584), the phase balancing circuit 48 controls one or more of the switches S5-S12 to connect a next capacitor bank configuration defined by the capacitor array 60.

When all the capacitor bank configurations defined by the capacitor array 60 have been tested with respect to the second receiver coil Rx2 (“YES” at block 580), the pre-balance controller 56 disconnects the capacitor array 60 from the second receiver coil Rx2 (e.g., by opening the switch S3) (at block 588).

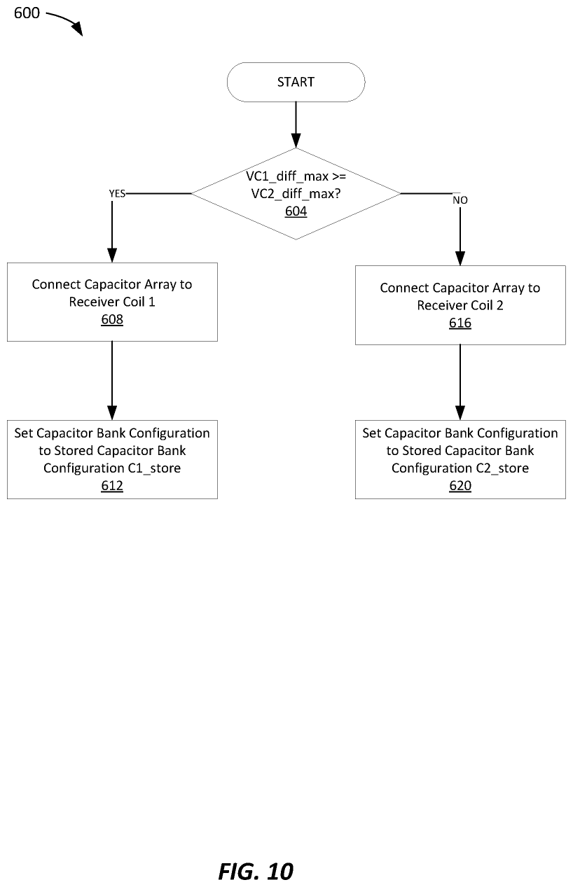

FIG. 10 illustrates a method 600 implemented by, for example, the pre-balance controller 56, for assigning a capacitor bank configuration to one of the first receiver coil Rx1, the second receiver coil Rx2, or neither receiver coil. The pre-balance controller 56 determines whether the largest voltage change VC1_diff_max associated with the first receiver coil Rx1 (e.g., determined at block 528 of the method 500) is larger than the largest voltage change VC2_diff_max associated with the second receiver coil Rx2 (e.g., determined at block 572 of the method 500) (at block 604).

When the largest voltage change VC1_diff_max associated with the first receiver coil Rx1 is larger than the largest voltage change VC2_diff_max associated with the second receiver coil Rx2 (“YES” at block 604), the pre-balance controller 56 connects the capacitor array 60 to the first receiver coil Rx1 (at block 608). The pre-balance controller 56 also sets the capacitor bank configuration of the capacitor array 60 to the stored capacitor bank configuration C1_store associated with the first receiver coil Rx1 (at block 612). For example, the pre-balance controller 56 outputs a control signal to the phase balancing circuit 48 for controlling the capacitor array 60 to the capacitor bank configuration associated with the largest voltage change VC1_diff_max. However, in some instances, when the largest voltage change VC1_diff_max is associated with a capacitance of 0 farads applied to the first receiver coil Rx1, the pre-balance controller 56 disconnects the capacitor array 60 from both the first receiver coil Rx1 and the second receiver coil Rx2 (e.g., such that a capacitor bank configuration is assigned to neither receiver coil).

When the largest voltage change VC1_diff_max associated with the first receiver coil Rx1 is not larger than the largest voltage change VC2_diff_max associated with the second receiver coil Rx2 (“NO” at block 604), the pre-balance controller 56 connects the capacitor array 60 to the second receiver coil Rx2 (at block 616). The pre-balance controller 56 also sets the capacitor bank configuration of the capacitor array 60 to the stored capacitor bank configuration C2_store associated with the second receiver coil Rx2 (at block 620). For example, the pre-balance controller 56 outputs a control signal to the phase balancing circuit 48 for controlling the capacitor array 60 to the capacitor bank configuration associated with the largest voltage change VC2_diff_max. However, in some instances, when the largest voltage change VC2_diff_max is associated with a capacitance of 0 farads applied to the second receiver coil Rx2, the pre-balance controller 56 disconnects the capacitor array 60 from both the first receiver coil Rx1 and the second receiver coil Rx2 (e.g., such that a capacitor bank configuration is assigned to neither receiver coil).

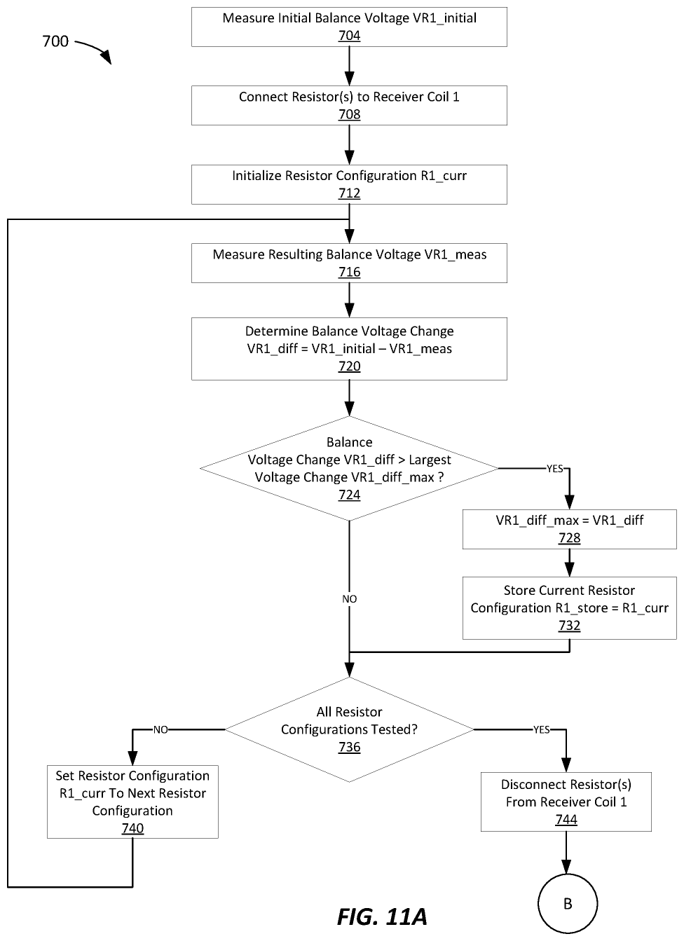

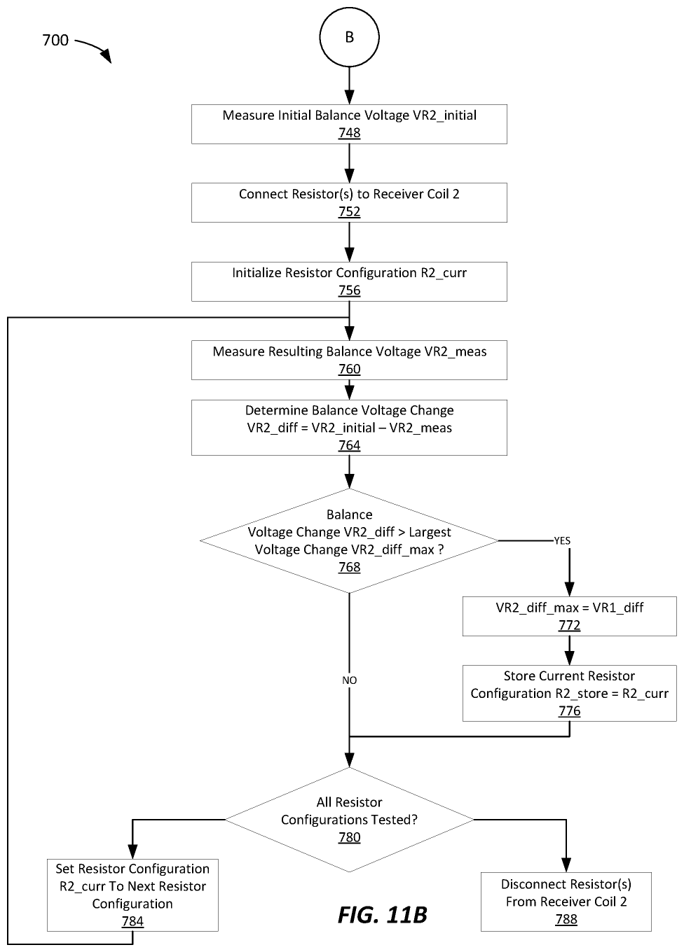

FIGS. 11A and 11B illustrate an example method 700 for selecting a resistor configuration of the variable resistor 64 to assign to one of the first receiver coil Rx1, the second receiver coil Rx2, or neither receiver coil (at block 212 of FIG. 6). Referring now to FIG. 11A, the method 700 includes measuring an initial balance voltage VR1_initial of the metal detector 20, for example, using the detection circuit 30 (at block 704). The initial balance voltage VR1_initial indicates a balance voltage of the metal detector 20 when no objects are present in the passageway 26 and resistance or resistance is applied to receiver coil Rx1 or receiver coil Rx2 (e.g., when all of switches S1-S4 are open).

The pre-balance controller 56 connects the variable resistor 64 to the first receiver coil Rx1 (e.g., by closing the switch S2) (at block 708), and initializes a resistor configuration R1_curr of the variable resistor 64 (at block 712) by outputting a control signal to the amplitude balancing circuit 52. The pre-balance controller 56 may initialize the resistor configuration R1_curr to a first resistance value of the predetermined range of resistance values of the variable resistor 64. For example, the initial resistor configuration R1_curr may be a resistor configuration associated with 0Ω, associated with a smallest resistance (e.g., 100Ω), or associated with a largest resistor (e.g., 50 kΩ).

When the resistor configuration R1_curr is set, the pre-balance circuit 44 measures (e.g., by way of the detection circuit 40) a resulting balance voltage VR1_meas of the metal detector 20 (at block 716). The pre-balance controller determines a balance voltage change VR1_diff defined by the difference between the initial balance voltage VR1_initial and the resulting balance voltage VR1_meas (at block 720).

The pre-balance controller 56 then determines whether the balance voltage change VR1_diff is greater than a largest voltage change VR1_diff_max (e.g., a greatest decrease in balance voltage) determined during a current execution of the method 700 (at block 724). For example, at an initial iteration of block 724, the value of VR1_diff_max may be zero. When the balance voltage change VR1_diff is greater than a largest voltage change VR1_diff_max (“YES” at block 724), the pre-balance controller replaces a stored value of the largest voltage change VR1_diff_max with the value of the balance voltage change VR1_diff (at block 728). When the balance voltage change VR1_diff is greater than a largest voltage change VR1_diff_max (“YES” at block 724), the pre-balance controller also stores resistor configuration R1_store with the current resistor configuration R1_curr (at block 732).

When the balance voltage change VR1_diff is not greater than a largest voltage change VR1_diff_max (“NO” at block 724), the method 700 proceeds to block 736. At block 736, the pre-balance controller 56 determines whether all resistor configurations have been tested with respect to the first receiver coil Rx1. When less than all the resistor configurations have been tested with respect to the first receiver coil Rx1 (“NO” at block 736), the pre-balance controller 56 outputs a control signal to the amplitude balancing circuit 52 to set the current resistor configuration R1_curr to a next resistor configuration (at block 740), and repeats the steps defined by blocks 716-744 of the method 700. For example, in response to receiving the control signal (e.g., generated at block 740), the resistance of the variable resistor 64 is increased to a next resistance level.

When all the resistor configurations defined by the variable resistor 64 have been tested with respect to the first receiver coil Rx1 (“YES” at block 736), the pre-balance controller 56 disconnects the variable resistor 64 from the first receiver coil Rx1 (e.g., by opening the switch S2) (at block 744).

Referring now to FIG. 11B, illustrating a continuation of the method 700, the pre-balance controller 56 measures an initial balance voltage VR2_initial of the metal detector 20 with variable resistor 64 disconnected from both the first receiver coil Rx1 and the second receiver coil Rx2 (at block 748). However, in some instances, the pre-balance controller 56 measures the initial balance voltage only once (e.g., at block 748).

The pre-balance controller 56 connects the variable resistor 64 to the second receiver coil Rx2 (e.g., by closing the switch S4) (at block 752), and initializes a resistor configuration R2_curr of the variable resistor 64 (at block 756) by outputting a control signal to the amplitude balancing circuit 52. The pre-balance controller 56 may initialize the resistor configuration R2_curr to a first resistance value of the predetermined range of resistance values of the variable resistor 64. For example, the initial resistor configuration R2_curr may be a resistor configuration associated with 0Ω, associated with a smallest resistance (e.g., 100Ω), or associated with a largest resistance (e.g., 50 kΩ).

When the resistor configuration R2_curr is set, the pre-balance circuit 44 measures (e.g., by way of the detection circuit 40) a resulting balance voltage VR2_meas of the metal detector 20 (at block 760). The pre-balance controller determines a balance voltage change VR2_diff defined by the difference between the initial balance voltage VR2_initial and the resulting balance voltage VR2_meas (at block 764).

The pre-balance controller 56 then determines whether the balance voltage change VR2_diff is greater than a largest voltage change VR2_diff_max (e.g., a greatest decrease in balance voltage) determined during a current execution of the method 700 (at block 768). For example, at an initial iteration of block 768, the value of VR2_diff_max may be zero. When the balance voltage change VR2_diff is greater than a largest voltage change VR2_diff_max (“YES” at block 768), the pre-balance controller replaces a stored value of the largest voltage change VR2_diff_max with the value of the balance voltage change VR2_diff (at block 772). When the balance voltage change VR2_diff is greater than a largest voltage change VR2_diff_max (“YES” at block 768), the pre-balance controller also stores resistor configuration R2_store with the current resistor configuration R2_curr (at block 776).

When the balance voltage change VR2_diff is not greater than a largest voltage change VR2_diff_max (“NO” at block 768), the method 700 proceeds to block 780. At block 780, the pre-balance controller 56 determines whether all resistor configurations have been tested with respect to the second receiver coil Rx2. When less than all the resistor configurations have been tested with respect to the second receiver coil Rx2 (“NO” at block 780), the pre-balance controller 56 outputs a control signal to the amplitude balancing circuit 52 to set the current resistor configuration R2_curr to a next resistor configuration (at block 784), and repeats the steps defined by blocks 760-788 of the method 700. For example, in response to receiving the control signal (e.g., generated at block 784), the resistance of the variable resistor 64 is increased to a next resistance level.

When all the resistor configurations defined by the variable resistor 64 have been tested with respect to the second receiver coil Rx2 (“YES” at block 780), the pre-balance controller 56 disconnects the variable resistor 64 from the second receiver coil Rx2 (e.g., by opening the switch S4) (at block 788).

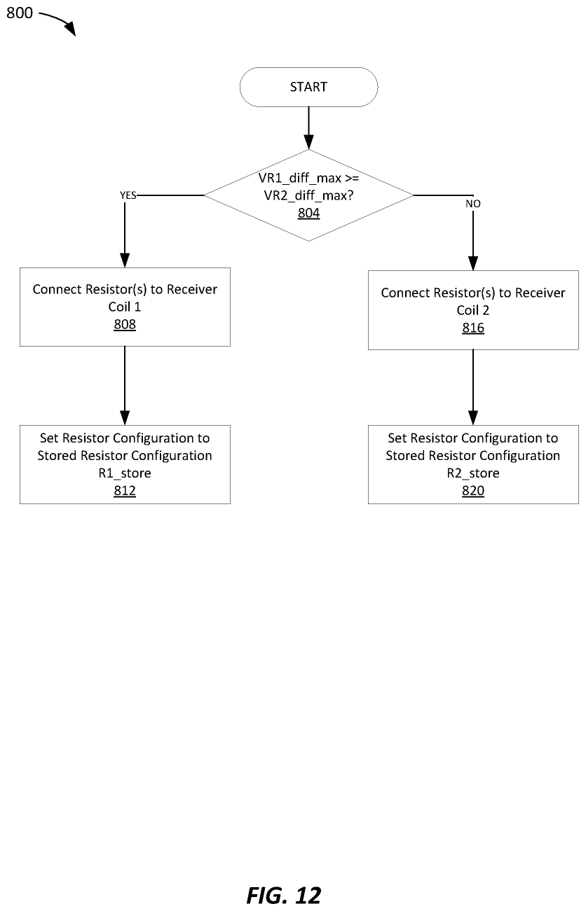

FIG. 12 illustrates a method 800 implemented by, for example, the pre-balance controller 56, for assigning a resistor configuration to one of the first receiver coil Rx1, the second receiver coil Rx2, or neither receiver coil. The pre-balance controller 56 determines whether the largest voltage change VR1_diff_max associated with the first receiver coil Rx1 (e.g., determined at block 728 of the method 700) is larger than the largest voltage change VR2_diff_max associated with the second receiver coil Rx2 (e.g., determined at block 772 of the method 700) (at block 804).

When the largest voltage change VR1_diff_max associated with the first receiver coil Rx1 is larger than the largest voltage change VR2_diff_max associated with the second receiver coil Rx2 (“YES” at block 804), the pre-balance controller 56 connects the variable resistor 64 to the first receiver coil Rx1 (at block 808). The pre-balance controller 56 also sets the resistor configuration of the variable resistor 64 to the stored resistor configuration R1_store associated with the first receiver coil Rx1 (at block 812). For example, the pre-balance controller 56 outputs a control signal to the amplitude balancing circuit 52 for controlling the variable resistor 64 to the resistor configuration associated with the largest voltage change VR1_diff_max. However, in some instances, when the largest voltage change VR1_diff_max is associated with a resistance of 0Ω applied to the first receiver coil Rx1, the pre-balance controller 56 disconnects the variable resistor 64 from both the first receiver coil Rx1 and the second receiver coil Rx2 (e.g., such that a resistor configuration is assigned to neither receiver coil).

When the largest voltage change VR1_diff_max associated with the first receiver coil Rx1 is not larger than the largest voltage change VR2_diff_max associated with the second receiver coil Rx2 (“NO” at block 804), the pre-balance controller 56 connects the variable resistor 64 to the second receiver coil Rx2 (at block 816). The pre-balance controller 56 also sets the resistor configuration of the variable resistor 64 to the stored resistor configuration R2_store associated with the second receiver coil Rx2 (at block 820). For example, the pre-balance controller 56 outputs a control signal to the amplitude balancing circuit 52 for controlling the variable resistor 64 to the resistor configuration associated with the largest voltage change VR2_diff_max. However, in some instances, when the largest voltage change VR2_diff_max is associated with a resistance of 0Ω applied to the second receiver coil Rx2, the pre-balance controller 56 disconnects the variable resistor 64 from both the first receiver coil Rx1 and the second receiver coil Rx2 (e.g., such that a resistor configuration is assigned to neither receiver coil).

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain implementations and should in no way be construed to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

The benefits, advantages, solutions to problems, and any element(s) that may cause any benefit, advantage, or solution to occur or become more pronounced are not to be construed as a critical, required, or essential features or elements of any or all the claims.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing,” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus.

Additionally, unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

The terms “substantially,” “essentially,” “approximately,” “about,” or any other version thereof, are defined as being close to as understood by one of ordinary skill in the art, and in one non-limiting example the term is defined to be within 10%, in another example within 5%, in another example within 1% and in another example within 0.5%. The term “coupled” as used herein is defined as connected, although not necessarily directly and not necessarily mechanically. A device or structure that is “configured” in a certain way is configured in at least that way but may also be configured in ways that are not listed.

Unless otherwise specified herein, the use of the ordinal adjectives “first.” “second.” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Unless otherwise specified herein, in addition to its plain meaning, the conjunction “if” may also or alternatively be construed to mean “when” or “upon” or “in response to determining” or “in response to detecting,” which construal may depend on the corresponding specific context. For example, the phrase “if it is determined” or “if [a stated condition] is detected” may be construed to mean “upon determining” or “in response to determining” or “upon detecting [the stated condition or event]” or “in response to detecting [the stated condition or event].”

It will be appreciated that some examples may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an example can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

It should also be understood that although certain drawings illustrate hardware and software located within particular devices, these depictions are for illustrative purposes only. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all of the multiple determinations, for example, collectively. To reiterate, those electronic processors and processing may be distributed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

Various features and advantages of the examples presented herein are set forth in the following claims.

What is claimed is:

1. A metal detector comprising:
a set of coils including a first receiver coil, a second receiver coil, and a transmitter coil;
an array of capacitor banks selectively connectable to one of the first receiver coil, the second receiver coil, or neither receiver coil, the array having a plurality of capacitor bank configurations, each capacitor bank configuration associated with a respective capacitance value;
at least one resistor selectively connectable to one of the first receiver coil, the second receiver coil, or neither receiver coil, the at least one resistor having a plurality of resistor configurations, each resistor configuration associated with a respective resistance value; and
an electronic processor configured to dynamically pre-balance the set of coils by:
selecting a capacitor bank configuration to assign to one of the first receiver coil, the second receiver coil, or neither receiver coil,
assigning the selected capacitor bank configuration to one of the first receiver coil, the second receiver coil, or neither receiver coil,
selecting a resistor configuration to assign to one of the first receiver coil, the second receiver coil, or neither receiver coil, and
assigning the selected resistor configuration to one of the first receiver coil, the second receiver coil, or neither receiver coil.

2. The metal detector of claim 1, wherein the electronic processor is configured to select the capacitor bank configuration to assign to one of the first receiver coil, the second receiver coil, or neither receiver coil by:
for the first receiver coil, selectively connecting each of the plurality of capacitor bank configurations to the first receiver coil and measuring first resulting balance voltages associated with each respective capacitor bank configuration when the respective capacitor bank configuration is connected to the first receiver coil;
for the second receiver coil, selectively connecting each of the plurality of capacitor bank configurations to the second receiver coil and measuring second resulting balance voltages associated with each respective capacitor bank configuration when the respective capacitor bank configuration is connected to the second receiver coil; and
selecting a capacitor bank configuration associated with a lowest resulting balance voltage of the first resulting balance voltages and the second resulting balance voltages.

3. The metal detector of claim 2, wherein the selected capacitor bank configuration is assigned to a receiver coil associated with the lowest resulting balance voltage.

4. The metal detector of claim 2, wherein, when the selected capacitor bank configuration is associated with a capacitance value of zero farads, the selected capacitor bank configuration is assigned to neither receiver coil, and
when the selected capacitor bank configuration is associated with a capacitance value greater than zero farads, the selected capacitor bank configuration is assigned to a receiver coil associated with the lowest resulting balance voltage.

5. The metal detector of claim 1, wherein the electronic processor is configured to select the resistor configuration to assign to one of the first receiver coil, the second receiver coil, or neither receiver coil by:
for the first receiver coil, selectively connecting each of the plurality of resistor configurations to the first receiver coil and measuring first resulting balance voltages associated with each respective resistor configuration when the respective resistor configuration is connected to the first receiver coil;
for the second receiver coil, selectively connecting each of the plurality of resistor configurations to the second receiver coil and measuring second resulting balance voltages associated with each respective resistor configuration when the respective resistor configuration is connected to the second receiver coil; and
selecting a resistor configuration associated with a lowest resulting balance voltage of the first resulting balance voltages and the second resulting balance voltages.

6. The metal detector of claim 5, wherein the selected resistor configuration is assigned to a receiver coil associated with the lowest resulting balance voltage.

7. The metal detector of claim 5, wherein, when the selected resistor configuration is associated with a resistance value of zero ohms, the selected resistor configuration is assigned to neither receiver coil, and
when the selected resistor configuration is associated with a resistance value greater than zero ohms, the selected resistor configuration is assigned to a receiver coil associated with the lowest resulting balance voltage.

8. The metal detector of claim 1, wherein the array of capacitor banks is an 8 bit array having 256 capacitor bank configurations.

9. The metal detector of claim 8, wherein capacitance values associated with the plurality of capacitor bank configurations range from 0 picofarads (“pf”) to 25.5 nanofarads (“nf”) with a resolution of 100 pf.

10. The metal detector of claim 1, wherein the array of capacitor banks is a 12 bit array having 4096 capacitor bank configurations.

11. The metal detector of claim 1, wherein the at least one resistor is a variable resistor.

12. The metal detector of claim 11, wherein the electronic processor is configured to dynamically pre-balance the set of coils in response to receiving a power on signal.

13. The metal detector of claim 1, wherein the electronic processor is configured to assign the selected capacitor bank configuration to one of the first receiver coil, the second receiver coil, or neither receiver coil before selecting a resistor configuration to assign to one of the first receiver coil, the second receiver coil, or neither receiver coil.

14. The metal detector of claim 1, wherein the electronic processor is further configured to, after dynamically pre-balancing the set of coils, precision balance the set of coils.

15. A method for dynamically pre-balancing a metal detector, the method comprising:
selecting one of a plurality of capacitor bank configurations defined by an array of capacitor banks to assign to one of a first receiver coil, a second receiver coil, or neither receiver coil, wherein each capacitor bank configuration is associated with a respective capacitance value;
assigning the selected one of the plurality of capacitor bank configurations to one of the first receiver coil, the second receiver coil, or neither receiver coil;
selecting one of a plurality of resistor configurations defined by at least one resistor to assign to one of the first receiver coil, the second receiver coil, or neither receiver coil, wherein each resistor configuration associated with a respective resistance value; and
assigning the selected resistor configuration to one of the first receiver coil, the second receiver coil, or neither receiver coil.

16. The method of claim 15, wherein selecting one of the plurality of capacitor bank configurations to assign to one of the first receiver coil, the second receiver coil, or neither receiver coil includes:
for the first receiver coil, selectively connecting each of the plurality of capacitor bank configurations to the first receiver coil and measuring first resulting balance voltages associated with each respective capacitor bank configuration when the respective capacitor bank configuration is connected to the first receiver coil;
for the second receiver coil, selectively connecting each of the plurality of capacitor bank configurations to the second receiver coil and measuring second resulting balance voltages associated with each respective capacitor bank configuration when the respective capacitor bank configuration is connected to the second receiver coil; and
selecting a capacitor bank configuration associated with a lowest resulting balance voltage of the first resulting balance voltages and the second resulting balance voltages.

17. The method of claim 15, wherein selecting one of the plurality of resistor configurations to assign to one of the first receiver coil, the second receiver coil, or neither receiver coil includes:
for the first receiver coil, selectively connecting each of the plurality of resistor configurations to the first receiver coil and measuring first resulting balance voltages associated with each respective resistor configuration when the respective resistor configuration is connected to the first receiver coil;
for the second receiver coil, selectively connecting each of the plurality of resistor configurations to the second receiver coil and measuring second resulting balance voltages associated with each respective resistor configuration when the respective resistor configuration is connected to the second receiver coil; and
selecting a resistor configuration associated with a lowest resulting balance voltage of the first resulting balance voltages and the second resulting balance voltages.

18. A balancing circuit for a metal detector, the balancing circuit comprising:
an array of capacitor banks selectively connectable to one of a first receiver coil, a second receiver coil, or neither receiver coil, the array having a plurality of capacitor bank configurations, each capacitor bank configuration associated with a respective capacitance value;
at least one resistor selectively connectable to one of the first receiver coil, the second receiver coil, or neither receiver coil, the at least one resistor having a plurality of resistor configurations, each resistor configuration associated with a respective resistance value; and
an electronic processor configured to dynamically pre-balance the metal detector by:
selecting a capacitor bank configuration to assign to one of the first receiver coil, the second receiver coil, or neither receiver coil,
assigning the selected capacitor bank configuration to one of the first receiver coil, the second receiver coil, or neither receiver coil,
selecting a resistor configuration to assign to one of the first receiver coil, the second receiver coil, or neither receiver coil, and
assigning the selected resistor configuration to one of the first receiver coil, the second receiver coil, or neither receiver coil.

19. The balancing circuit of claim 18, wherein the electronic processor is configured to select the capacitor bank configuration to assign to one of the first receiver coil, the second receiver coil, or neither receiver coil by:
for the first receiver coil, selectively connecting each of the plurality of capacitor bank configurations to the first receiver coil and receiving a measured first resulting balance voltages associated with each respective capacitor bank configuration when the respective capacitor bank configuration is connected to the first receiver coil;
for the second receiver coil, selectively connecting each of the plurality of capacitor bank configurations to the second receiver coil and receiving a measured second resulting balance voltages associated with each respective capacitor bank configuration when the respective capacitor bank configuration is connected to the second receiver coil; and
selecting a capacitor bank configuration associated with a lowest resulting balance voltage of the first resulting balance voltages and the second resulting balance voltages.

20. The balancing circuit of claim 18, wherein the electronic processor is configured to select the resistor configuration to assign to one of the first receiver coil, the second receiver coil, or neither receiver coil by:
for the first receiver coil, selectively connecting each of the plurality of resistor configurations to the first receiver coil and receiving measured first resulting balance voltages associated with each respective resistor configuration when the respective resistor configuration is connected to the first receiver coil;
for the second receiver coil, selectively connecting each of the plurality of resistor configurations to the second receiver coil and receiving measured second resulting balance voltages associated with each respective resistor configuration when the respective resistor configuration is connected to the second receiver coil; and
selecting a resistor configuration associated with a lowest resulting balance voltage of the first resulting balance voltages and the second resulting balance voltages.
